(19) United States
(12) Patent Application Publication
(10) Pub. No.: US 2003/0192645 A1
(43) Pub. Date: Oct. 16, 2003

(54) Method and apparatus for creating circumferential process gas flow in a semiconductor wafer plasma reactor chamber

(75) Inventors: Jingboa Liu, Sunnyvale, CA (US); Taeho Shin, San Jose, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 10/124,535

(22) Filed: Apr. 16, 2002

(51) Int. Cl. C23F 1/00; C23C 16/00

(52) U.S. Cl. 156/345.33; 118/715

(57) ABSTRACT

A method and apparatus is disclosed for circumferential process gas flow in an ion etch or deposition plasma reactor. The process includes a method and apparatus for creating a flow of the desired gas, circumferentially around the outer edge portion of a semiconductor wafer positioned within a plasma reactor chamber. At least a portion of the desired gas is in a plasma state.

### BACKGROUND OF THE INVENTION

1. Field of the Invention

The present invention relates to an apparatus and a method for delivery of process gases to a semiconductor wafer in a plasma-processing environment. More particularly, the present invention relates to an apparatus and method for creating circumferential flow of process gases, at least a portion of which becomes a plasma, in a semiconductor wafer plasma-processing chamber to maximize processing uniformity and obtaining the most favorable results from such processing by reason of such flow.

2. Background of the Related Art

Gas plasma reactors have an enclosed chamber formed by a ceiling, floor and sidewall and within which a reactant plasma environment is created. These types of reactors are widely used in processing semiconductor wafers in the fabrication of semiconductor integrated circuits.

Two related fabrication processes for integrated circuit production on a wafer using a gas plasma reactor are plasma etching and plasma-enhanced chemical vapor deposition (CVD). In both of these processes, a wafer is placed substantially horizontal on the surface of a support member within the chamber of the plasma reactor. A processing gas is then introduced into the chamber (usually under a vacuum). The process gas is then energized with an energy source capable of changing the process gas into a plasma state in the chamber. Only a portion of the process gas may be in a plasma state during the etching or deposition process. The process gas becomes a plasma at the point it is subjected to an appropriate plasma energy source such as might be obtained from radio frequency energy or microwave energy.

Conventionally, plasma excitation is performed by capacitively or inductively coupling radio frequency (RF) energy through the chamber. RF power can be applied to a wafer mounting support, for example, and create a DC bias voltage across the sheath of the gas plasma next to the wafer and control the energy of ions expelled from the plasma gas toward the wafer. Plasma-excited processing gas and its ions and radicals then interact with the uppermost exposed surface of the wafer. In the etching process, ions from the plasma processing gas remove parts of one or more layers of the wafer. Likewise, in chemical vapor deposition, ions from the plasma processing gas are deposited on the wafer.

In various types of plasma processing of wafers, the processing gas is entrained in an inactive carrier gas, and both gases are excited into a plasma state. A carrier gas can be selected for use for a number of reasons. The carrier gas produces a higher chamber pressure and thus can help to sustain the plasma pressure above a critical minimum pressure needed for processing of the wafer than would be the case with a processing gas alone. The carrier gas also can act as a diluent and promotes uniformity of the etching or deposition process. In the etching process, a carrier gas can balance the electro-negativity of the plasma. The energy of the carrier gas ions impinging upon the wafer being processed also helps to activate the reaction between the bonded atoms of the wafer and the active components of the plasma gas. Argon is a typical carrier gas used in etching, but helium is another common carrier gas.

Because of the advantages of processing more chips at once, the commercial trend in semiconductor chip manufacture is toward larger diameter semiconductor wafers and producing smaller integrated circuit elements on each chip. Several processing problems have arisen, especially in the etching process, as a result of these trends.

Vias and contacts now can be as small in width as 0.18 μm. Fabrication of via and contact holes of 0.13 μm widths are being readied for commercialization and via and contact hole widths of 0.10 μm are expected in the not too distant future.

These increasingly small widths present difficult etching problems, particularly in view of the thickness of the dielectric layer on the uppermost surface of the wafer remaining essentially constant. This difficulty is primarily due to via holes having increasingly high aspect ratios as widths decrease. The aspect ratio of a via hole is the ratio between the depth of the hole to the narrowest dimension of the hole in its upper portion. At the present time, aspect ratios of 4 or 5 are found in advanced chips. In future chips, the aspect ratio may increase to 8 or 10 or higher. Such high aspect ratios present a significant challenge to etching because they require a highly directional or anisotropic etch that reaches deeply into the hole.

The critical measure of the utility of a new etching process or of an old etching process when practiced with a new etching apparatus, is the measure of the uniformity of the process across the wafer. Etch uniformity refers to the difference in the etching rate between the chips located in the center of the wafer and the chips located at the edge of the wafer. Concomitant concerns are the uniformity or reproducibility of the etch results from wafer to wafer and the uniformity in the removal of photoresist across the surface of the wafer.

Uniformity is considered a statistical problem with random distributions having a median value but with wide distribution about the median. The median value μ of the distribution is not usually a problem since the process timing can be adjusted. However, the standard deviation σ (here defined simply as the average deviation from the median) does present a problem. For integrated circuits having millions of devices and requiring hundreds of steps to manufacture, a failure of any one of those devices caused by any one of the steps of the production of the device will produce a defective chip. As a result, if a process produces a measured mean μ and standard deviation σ, and μ+σ and μ−σ fall well within the predicted window of operability for the device, the statistics may be totally unsatisfactory if the statistics over the entire device and process require a confidence level of, for example, 5σ to attain an acceptable defect level. That is, the satisfactory device parameters must fall between μ+5σ and μ−5σ. Accordingly, a must be reduced and deformities over the entire wafer of 10% or even less than 5% are required.

Processing gas is usually injected into a wafer plasma reactor chamber through one or more gas distributing apparatus connected to a gas supply and arranged in a somewhat similar geometry located in either the chamber's ceiling, floor or sidewall. Such apparatus for supplying gas to a plasma reactor chamber are well known and typically provide means for delivering the gas to the chamber by one or more apertures (holes). For example, the gas distribution apparatus may be in the form of a showerhead having a large number of small apertures distributed over the area of the showerhead corresponding roughly to the area of the wafer and directed at the wafer. Another example of a gas distribution apparatus is a gas distribution ring having multiple apertures arranged to direct the gas toward the wafer.

In yet a further example, the gas distribution apparatus is in the form of injectors, typically a hollow protrusion resembling a finger with multiple apertures. The injectors are positioned in the ceiling of the reactor chamber with the apparatus oriented to face the exposed surface of the wafer and in operation distributes gas across the wafer surface. Commercial embodiments of this arrangement generally have four equally spaced injectors with apertures for distributing process gas. Each injector distributes the process gas in a 360° pattern perpendicular to the chamber wall and directly towards the wafer.

Other gas injection systems have been used to provide more uniform results in the etching processing of semiconductor wafers. In general, these methods involve directing gas flow from multiple injectors or other gas distribution apparatus towards the periphery of a wafer at an angle toward the center of the wafer which result in more process gas at the center of the wafer than at the outer edge portion. Other methods used in plasma gas processing include injecting gas from the periphery radially into the chamber toward the center of the wafer while a second gas is injected at acute angles toward the wafer again leaving more process gas at the center of the wafer than at the outer edge portion. Another method employed is to have multiple injectors with apertures positioned to create a vortex around each injector. However, none of these known gas distribution apparatuses adequately resolve problems associated with microloading, etch stop or uniformity.

### SUMMARY OF THE INVENTION

It can be seen from the foregoing description that the problems with plasma processing of a semiconductor wafer by plasma etching are well known within the art. The main problems, as previously stated, relate to uniformity, microloading and etch stop on the wafer. Other concerns relate to maintaining chamber size as small as possible in relationship to the wafer. As wafers become increasingly layered, components on the chip increasingly smaller, wafers larger and via's smaller, it becomes proportionally more important to control these problems. Most gas plasma reactors use a gas flow system which provides even gas flow in the chamber across the surface of the wafer. Since the outer edge portion of the wafer reacts faster than the center portion, directional attempts have been made to alter gas flow direction towards the center of the wafer.

A feature of this invention resides in the discovery that the problems described above can be greatly reduced by use of a substantially circular or circumferential gas flow within the enclosed chamber of a plasma reactor during the etching or deposition process. The enclosed chamber comprises a floor, sidewall and ceiling. While the process gas is flowing substantially circumferentially, at least a portion of the process gas is energized to a plasma state sufficient to effect the etching or deposition process to the wafer. While process gas is delivered to the entire exposed surface of the wafer, a substantially circumferential gas flow is created over the outer edge portion of the wafer and preferably the outer quarter to half of the exposed surface of the wafer. The actual area which constitutes the outer edge portion is variable and may be more or less based on the size of the wafer, the processing gas selected and the like. Circumferential gas flow in either clockwise or counter-clockwise direction is contemplated according to the invention.

Process gas flow into the enclosed chamber is achieved by use of at least one gas distribution apparatus. Each gas distribution apparatus has at least one process gas flow aperture. (The number, exact position and size of the apertures can vary as needed to achieve the results described for different processing schemes.) The combined flow from all the process gas flow apertures in a single gas distribution apparatus will create a spray of process gas. The gas distribution apparatus apertures are positioned in the chamber so that the direction of the spray from each apparatus is along “a directed spray vector” which refers to the overall general direction of the spray. Substantially circumferential flow is created by having at least one gas distribution apparatus positioned in the reactor chamber with the process gas flow apertures arranged such that process gas spray is directed toward the chamber sidewall away from the center of the wafer. The process gas spray directional vector as viewed in plan is oriented at an angle such that as the gas rebounds off the walls of the chamber, the spray from each of the gas distribution apparatus, in concert, assumes a substantially circumferential gas flow over the exposed outer edge portion of the wafer. This vector is greater than 0° and less than 180° as measured from the sidewall of the plasma reactor chamber, away from the center of the wafer. The spray can be in either a clockwise or counter-clockwise direction.

The exact number and type of gas distribution apparatus and apertures therein, as well as their location will vary according to the size of the chamber and wafer, the gas flow pressure, the size, shape, and orientation of the apertures in the apparatus, in the ceiling, floor or sidewall required to achieve substantially circumferential gas flow but from the disclosure of applicant, can be determined by one skilled in the art. The gas distribution apparatus may be any type suitable for use in a gas plasma reactor or useful in creating the desired flow. For instance, it can be a showerhead, ring or other type apparatus located in the plasma reactor chamber ceiling, floor or sidewall, as desired. The apparatus can also comprise apertures directly in the floor, sidewall or ceiling. In addition, such gas distribution apparatus can be at multiple locations and/or use multiple types of gas distribution apparatus.

Exemplary gas distribution apparatus of the invention are the injector type with multiple apertures and positioned in the ceiling of the enclosed chamber of the plasma reactor. When injectors are used, each injector is provided with sufficient apertures positioned to generate a directed spray having a directional vector which in turn creates a circumferential flow over the outer edge portion of a wafer. In one embodiment, the injectors are mounted to a common gas chamber which equalize pressure in each injector regardless of where placed in the chamber. Exemplary gas flow rate from the injectors is in the 500-700 SCCM range, and the pressure created during etching or deposition is in the 10-50 mT range.

The gas distribution apparatuses of the invention are connected to at least one gas supply, directly or indirectly, by means known in the art. One or more gas feed lines may be employed to respectively connect each gas distribution apparatus to at least one gas supply which contains at least one gas that is fed to the gas distribution apparatus via the respective gas feed line. The gas supply is either an active process gas supply or a supply of secondary gas supply inactive to the etching or deposition process. The gas supply can be made up of one gaseous specie or species, or can contain a gas made of a different specie or species. In fact, different gas supplies can contain different types of both active and inactive gases. Alternatively, if there is no requirement to deliver different gases to the chamber, each of the gas distribution apparatus can be connected to a single gas supply. Gases include active process gases, that is those for etching purposes, deposition, and inert gases such as a carrier gas. Other gases known in the art may, of course, be used as well.

It is desired that gas be delivered to the enclosed plasma reactor chamber in a substantially uniform manner. To this end, the gas distribution apparatus of the invention may be equally spaced in relation to one another around the chamber and each has an equal number and arrangement of apertures therein. In addition, a uniform gas distribution typically requires that the gas flow rate from each aperture and each apparatus as a whole be approximately the same. Gas distribution apparatus, according to the present invention, are capable of providing a range of gas pressure and flow rates. This can be achieved by methods well known in the art. Thus, whenever a uniform gas distribution is required, all the apparatus may be configured to produce the same flow rate. One way of establishing the differing gas flow rates is to vary the gas pressure in the gas supplies (where separate gas supplies are employed). Another way is to adjust the configuration of the apertures themselves.

While the plasma energy source can be turned on at any stage of the processing, the process gas may enter the enclosed chamber and begin its circumferential flow before being subjected to energy from such source.

The circumferential gas distribution apparatus of the invention may be sealed to prevent gases from leaking between different parts of the apparatus, and between the apparatus and the chamber sidewall and ceiling. Accordingly, various sealing devices, such as sealing O-rings can be employed. One such sealing device prevents the passage of gases to or from the reactor chamber.

While the present invention is directed primarily to the etching process, it will be clear from the disclosure and results obtained from the invention that the invention process is equally applicable to the deposition process.

### BRIEF DESCRIPTION OF THE DRAWINGS

FIG. 1 is a top plan and schematic view of a reactor chamber of an apparatus configuration indicating 360° radial flow from apertures positioned in each of the injectors, as further illustrated in FIG. 4.

FIG. 2 is a top plan and schematic view of a reactor chamber according to an exemplary embodiment of the invention indicating process gas spray from the injectors, as further illustrated in FIG. 5A, and which result in the illustrated circumferential gas flow.

FIG. 3 is an enlarged fragmentary view of a reactor chamber illustrating a single gas distribution apparatus embodiment of the invention and which indicates the directional spray vector of the process gas discharged from each injector as depicted in FIG. 2.

FIG. 4 is a side elevation section and schematic view of a standard gas supply and reactor apparatus illustrating the apertures in a typical type of injector gas distribution apparatus used in commercial applications.

FIG. 5A is a side elevation section and schematic view of a process gas supply and the apertures in an injector type embodiment of a gas distribution apparatus according to an embodiment of the invention.

FIG. 5B is a perspective view of an injector type embodiment of a gas distribution apparatus according to an embodiment of the invention.

FIGS. 6A, 6B and 6C are exemplary overall schematic side section views of a first, second, and third embodiment of a plasma reactor system having a gas supply, a plasma energy source, injector type gas distribution apparatus and a plasma chamber showing the ceiling, floor and sidewall.

FIG. 7 is a side elevation and schematic view of a showerhead type distribution apparatus.

FIG. 8 is a side elevation and schematic view of an injector apparatus according to another exemplary embodiment of the invention.

### DESCRIPTION OF THE EXEMPLARY EMBODIMENTS

In an exemplary embodiment of the present invention, four vertical gas delivery injectors are located in the ceiling of an enclosed plasma gas reactor chamber also having a sidewall and floor and are equally spaced and positioned directly above the outer edge portion of a semiconductor wafer. Each injector has at least one aperture which creates a process gas spray pattern of from about 30° to about 90° or more in width as viewed in FIGS. 2 and 3 relative to the central vertical axis of the injector apparatus and generally has a directional spray vector 28 roughly in the middle of the spray pattern. A circumferential process gas flow, as further depicted by FIGS. 2 and 3, is created by the combined effect of each of the sprays from the injectors by reason of each of the directional vectors being pointed at an angle greater than 0° and less than 180° toward the chamber sidewall and away from the wafer center portion, with all of such vectors being in either clockwise or counter-clockwise direction. It is possible to make this angle variable by making the injector rotatable around its axis. The plasma gas spray from each injector bounces off the sidewall and in combination with spray from other injectors assumes a circumferential flow in the chamber. The flow is generally over the outer edge portion of the wafer. A plasma energy source, such as a radio frequency energy or microwave energy, is used to create a plasma of at least a portion of the gas once the gas has passed into the chamber. According to one aspect of the invention, each injector has the apertures aligned at relatively the same angle when viewed in elevation as in FIG. 5A. A beneficial angle, as viewed in plan, is from about 25°-75° and in the embodiment is about 45°. The plasma gas injectors can optionally be adjusted variably, for example by rotation, independently or in unison resulting in the directional spray vector changing accordingly.

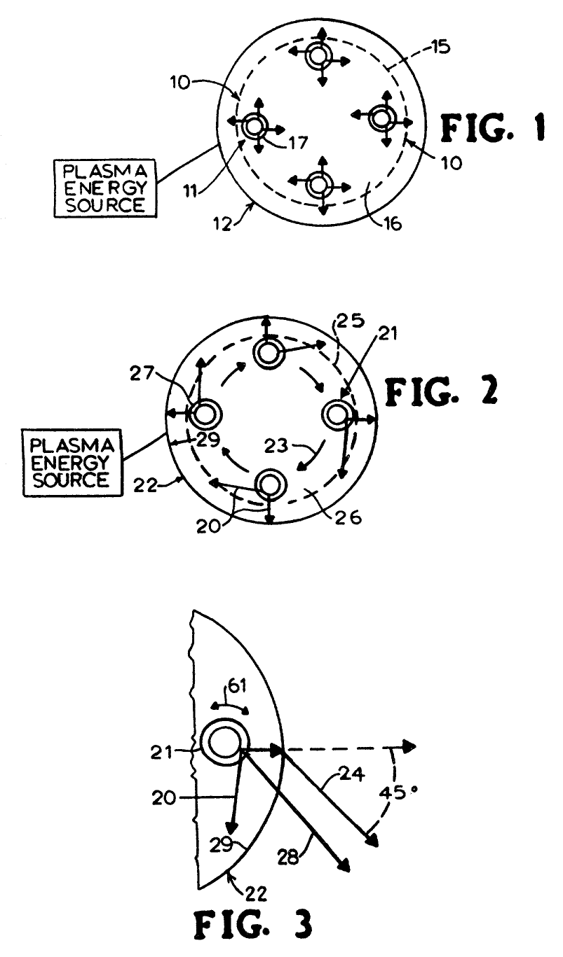

FIG. 1 represents a top plan and schematic view of a plasma reactor chamber showing an arrangement of plasma gas injectors. In the figure, there are four gas injectors 11 equally spaced in the ceiling of plasma reactor chamber 12 and attached to the ceiling via mounting rings 17. The spray pattern from each injector 11 is represented by arrows 10 which indicate 360° radial gas flow from each injector. It can be seen that the spreading reactant gas is essentially omni directional over the surface of the wafer 15 even though the injectors are positioned over the outer edge portion 16 of the wafer. A plasma energy source is positioned to convert the process gas to a plasma state.

FIG. 2 represents a top plan and schematic view of a plasma reactor chamber according to an exemplary embodiment of the invention. A plasma reactor chamber is shown with four gas injectors 21 positioned in reactor chamber 22 over wafer 25 and mounted to the ceiling of the reactor via mounting rings 27. The angular width of the spray from each of the injectors is noted by arrows marking the boundary of the spray 20 from injectors 21. The process gas is shown being sprayed toward sidewall 29. The net effect of spray 20 produces a directional spray vector 28 (see FIG. 3). Each of injectors 21 produces a similar directional spray vector 28, and each directional spray vector 28, acting in concert, creates a clockwise circumferential process gas flow 23 (see FIG. 2) over the outer edge portion 26 of wafer 25. It is easy to see that a reversal of the position of the injectors and thus the angle of the directional spray vector could create a counter-clockwise gas flow. A plasma energy source is positioned to convert the circumferential process gas flow to a plasma state for etching or deposition.

FIG. 3 shows an enlarged fragmentary view of a plasma reactor chamber 22 showing a single gas distribution injector from FIG. 2. Spray 20 from injector 21 has directional spray vector 28 toward the sidewall 29. The result of all four injectors operating simultaneously is to produce the circumferential flow 23 illustrated in FIG. 2. Also shown is that, optionally, the direction the injector faces can be made to rotate axially (see 61 in FIG. 3) in order to variably adjust the direction of directional spray vector 24 relative to the sidewall 29 of the chamber.

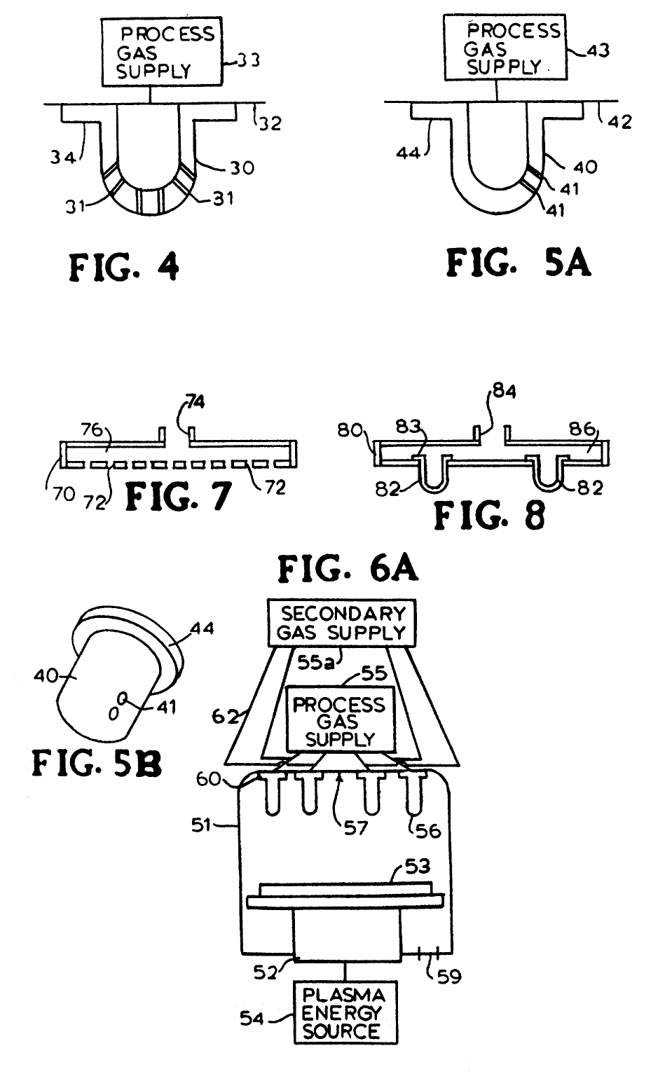

FIG. 4 shows a side elevation section and schematic view of a gas plasma injector used in commercial applications. The injector 30 has multiple apertures 31 which deliver process gas from the process gas supply 33. The injector 30 is mounted in the reactor chamber ceiling 32 via mounting rings 34. When process gas flows from the apertures, the apparatus produces a 360° process gas spray pattern with no directional spray vector.

FIG. 5A shows a side elevation section and schematic view and 5B a perspective view of a gas plasma injector 40 according to the first embodiment of the invention. Injector 40 is mounted in the enclosed plasma reactor chamber ceiling 42 via mounting rings 44. Due to the position of the apertures 41 on only one side of each injector, the process gas from the process gas supply 43 will exit the apparatus aperture as a directed spray having a directional spray vector toward the sidewall of the chamber and away from the wafer center as illustrated in FIGS. 2 and 3.

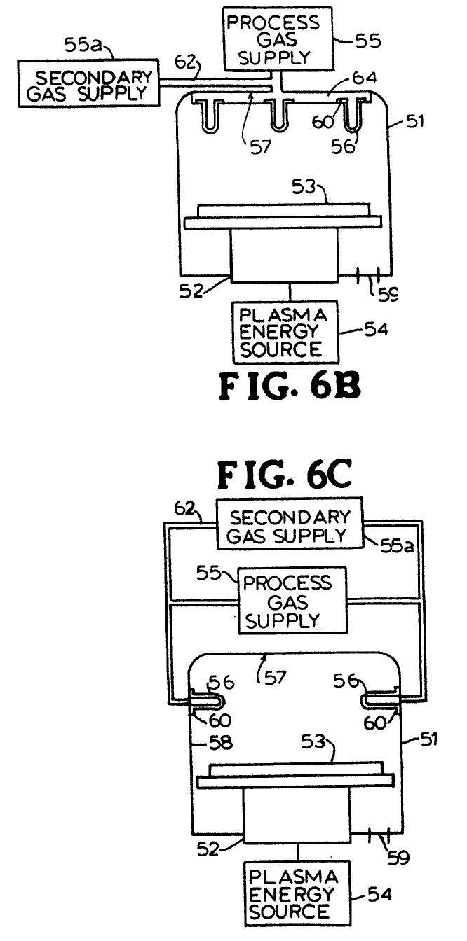

FIGS. 6A, 6B, and 6C all show an overall schematic side section view of different embodiments of a plasma reactor chamber 51 according to the invention. In chamber 51 is a member support 52 which has the wafer 53, to be treated, positioned essentially centrally and horizontally thereon. In addition, a plasma energy source 54 is connected to provide radio frequency energy or other energy to convert the process gas from process gas supply 55 or secondary gas supply 55a to a plasma state. In FIGS. 6A and 6B, injectors 56 are shown positioned in the reactor chamber ceiling 57 via mounting rings 60. In FIG. 6A, the injectors are mounted directly in the ceiling each with its own gas feed line 62. In FIG. 6B, the injectors 56 are mounted in a common gas feed chamber 64 which equalizes pressure to each of the injectors 56. Any number of injectors can be mounted in the gas feed chamber and the chamber will equalize pressure. It would therefore be a simple matter to add injectors. In FIG. 6C, the injectors 56 are mounted to the sidewall 58 of the chamber and via mounting rings 60. Process gas and/or secondary gas are withdrawn from chamber 51 via gas exhaust 59.

FIG. 7 shows a side elevation section and schematic view of a showerhead type distribution apparatus 70 showing apertures 72 and gas inlet 74 to gas distribution chamber 76. Gas entering gas distribution chamber 76 evenly exits apertures 72 and is designed to produce an even distribution of gas within a reactor chamber 51.

FIG. 8 shows a side elevation and schematic view of an injector apparatus 80 showing injectors 82 with mounting rings 83 and gas inlet 84 which can distribute gas to a distribution chamber 86. Injectors 40 from FIGS. 5A and 5B can be used to create the flow of the present invention.

Systematic studies, under the direction of the inventors, were conducted comparing the results of gas plasma etching using a standard set of four gas injectors to the results of gas plasma etching using a set of four gas injectors according to the present invention. Each injector in the standard set of four gas injectors produced a non-directional 360° spray pattern within the reactor chamber. Each injector in the set of four gas injectors according to the present invention was provided with apertures that produced a directional spray vector, the combination of which created a circumferential process gas flow around the outer edge portion of a wafer. This particular study used a 45° directional spray vector relative to the sidewall and away from the center of the wafer. The gases used were fluorocarbon, oxygen, and argon, at a pressure of 40 mT. Gases were introduced into the chamber and then subjected to a plasma energy source to process the wafers.

According to a first aspect of the studies, a sample etch process was run according to the procedures noted above. Thereafter, samples were taken from the top, left, center, right and bottom portion of the wafer relative to the wafer notch. Etch uniformity was measured by measuring the etch depth at each location, and dividing that result by the etch time. The comparative results of this study are reported in Table 1 below.

TABLE 1
Etch Uniformity Improvement in Å/min

| | | Etch | Etch | Etch | Etch | Etch | |
|---|---|---|---|---|---|---|---|
| | | Depth | Depth | Depth | Depth | Depth | Etch |
| Injector | | at | at | at | at | at | Uniformity |
| Configuration | Feature | Top | Left | Center | Right | Bottom | (M − m)¹ |
| Standard | 0.25 μm Hole | 13653 | 16317 | 12821 | 15984 | 15651 | 11.7% |
| 360° Spray | 0.5 μm Hole | 17483 | 18149 | 15485 | 18315 | 18149 | 8.15% |
| | Open Site² | Deposition | Deposition | Deposition | Deposition | Deposition | N/A |
| | Open Pad³ | 5 | 5 | 4 | 5 | 5 | |
| 45° Vector | 0.25 μm Hole | 14985 | 15818 | 14153 | 15984 | 15818 | 6.0% |
| Spray | 0.5 μm Hole | 18482 | 17982 | 16650 | 18315 | 17483 | 5.2% |
| | Open Site² | 19980 | 18648 | 17982 | 16650 | 19481 | 9.0% |
| | Open Pad³ | 1 | 1 | 0 | 2 | 0 | |

¹“M”: Maximum etch rate; “m”: Minimum etch rate.
Uniformity is calculated then by taking the difference between the largest depth and smallest depth (or the thickness of the photoresist) etching at the tested locations and divided by 2 times the mean in percentage form.
²Open Site: Open site areas with photoresist but not intended for chip production. “Deposition” indicates a deposit was formed in the tested areas and no etching occurred.
³Open Pad: Open pad areas on the wafer with no photoresist intended for chip production. Rated 1-5 indicating the amount of residue at the open area; 0: nothing left; 5: no etch at all.

According to these test results, etch uniformity of a 0.25 μm hole using a standard gas injector set produced a relatively high etch uniformity error rate of 11.7%. The etch uniformity for the same size feature (0.25 μm hole) using the injector arrangement according to the present invention yielded an improved etch uniformity error rate of 6.0%. A similar improved etch uniformity is reported for a 0.5 μm hole feature where the standard injector arrangement produced a 8.15% etch uniformity error rate while the injector arrangement according to the present invention resulted in a reduced etch uniformity error rate of 5.2%.

Open Site areas are those areas with photoresist but not intended for chip production. In the Open Site areas in the standard injector arrangement, there was no etching, but instead there was measurable deposition of material. The injector arrangement according to the present invention did produce etching effects at the Open Sites, with an etch uniformity error rate of 9.0%. This indicates that even in areas of the wafer not intended to be subject to production, etching was still taking place with an unusually low etch uniformity error rate.

In the Open Pad areas of the wafer, those areas on the wafer with no photoresist intended for chip production, the amount of residue left in the Open Site area after processing was measured. This measure was rated on a scale of 0 to 5, 0 being the preferred indicator representing no material was left, and 5 indicating no etching took place at all. The standard injector configuration samples rated between 4 and 5 at all test locations, while the injector arrangement according to the present invention rated between 0 and 2. These test results illustrate dramatic improvement in wafer etch processing using the injector arrangement according to the invention over previously known injector arrangements.

According to a second aspect of the studies, another sample etch process was run according to the procedures noted above. Thereafter, samples were again taken from the top, left, center, right and bottom portion of the wafer relative to the wafer notch. Photo Resist (PR) uniformity was measured by dividing PR removal by time. The comparative results of this study are reported in Table 2 below

TABLE 2
Photo Resist (PR) Uniformity Improvement
Facet PR in Å/min

| | | | | | | | PR |
|---|---|---|---|---|---|---|---|
| Injector | | | | | | | Uniformity |
| Configuration | Feature | Top | Left | Center | Right | Bottom | (M − m)¹ |
| Standard 360° | 0.25 μm Hole | 5328 | 4829 | 5328 | 4829 | 4829 | 5.9% |
| Spray | 0.5 μm Hole | 4662 | 4995 | 5328 | 4829 | 4995 | 6.7% |
| | Open Site² | 4995 | 5328 | 4829 | 4995 | 4829 | 5.0% |
| 45° Vector | 0.25 μm Hole | 4829 | 4995 | 4829 | 4829 | 4829 | 1.7% |
| Spray | 0.5 μm Hole | 4662 | 4829 | 4496 | 4496 | 4496 | 3.6% |
| | Open Site² | 5328 | 4829 | 4496 | 5162 | 4496 | 8.6% |

The results presented in Table 2 illustrate similar improvements in PR uniformity across the wafer when using the injector arrangement according to the present invention. Those samples taken from the process using the present invention yielded 1.7%, 3.6%, and 8.6% PR uniformity error rates for 0.25 μm hole, 0.5 μm hole, and Open Site features, respectively. The standard injector arrangement resulted in 5.9%, 6.7%, and 5.0% PR uniformity error rates for 0.25 μm hole, 0.5 μm hole, and Open Site features, respectively. The injectors according to the present invention clearly and significantly lower PR uniformity error rates over the standard injector arrangement.

Although the invention has been described in detail by specific reference to preferred embodiments, particularly the etching process, it is understood that variations and modifications to gas distribution apparatus, apertures, angles, selected gases, energy sources and the like, may be made and the deposition process applied, according to the invention, without departing from the intended spirit and scope of the invention as claimed.

What is claimed is:

1. A semiconductor wafer plasma reactor system comprising:
(a) a plasma reactor having an enclosed chamber comprising a sidewall, a floor and a ceiling;
(b) a support member adapted for mounting a semiconductor wafer positioned in the chamber;
(c) a process gas supply;
(d) at least one process gas distribution apparatus positioned within the chamber at a predetermined location and adapted to receive gas from the process gas supply, each of the gas distribution apparatus comprising at least one process gas flow aperture, each of the gas distribution apparatus positioned at the predetermined location such that process gas flowing from its gas flow apertures creates a substantially circumferential process gas flow within the enclosed chamber along an outer edge portion of a semiconductor wafer positioned on the mounting surface of the support member; and
(e) an energy source adapted to convert at least a portion of process gas in the enclosed chamber into a plasma of selected density.

2. A semiconductor wafer plasma reactor system according to claim 1 wherein the process gas flowing from each gas distribution apparatus creates a directional spray vector of from greater than 0° to less than 180° relative to the sidewall of the enclosed chamber, away from the center of the wafer and toward the sidewall.

3. A semiconductor wafer plasma reactor system according to claim 2 wherein the spray directional vector is about 45°.

4. A semiconductor wafer plasma reactor system according to claim 1 wherein the energy source is a radio frequency energy source.

5. A semiconductor wafer plasma reactor system according to claim 1 wherein the energy source is a microwave energy source.

6. A semiconductor wafer plasma reactor system according to claim 1 wherein the process gas is a flurohydrocarbon gas.

7. A semiconductor wafer plasma reactor system according to claim 2 wherein the process gas distribution apparatus can be variably positioned, within the reactor chamber.

8. A semiconductor wafer plasma reactor system according to claim 1 which further comprises a secondary gas connected to the gas distribution apparatus.

9. A semiconductor wafer plasma reactor system according to claim 8 wherein the secondary gas supply comprises an inactive secondary gas.

10. A semiconductor wafer plasma reactor system according to claim 1 wherein each of the gas distribution apparatus is positioned in the reactor chamber ceiling.

11. A semiconductor wafer plasma reactor system according to claim 1 wherein the gas distribution apparatus is an injector.

12. A semiconductor wafer plasma reactor system according to claim 9 wherein the inactive gas is a carrier gas.

13. A process gas distribution device for use in a semiconductor wafer plasma chamber of a plasma reactor for processing a semiconductor wafer; comprising at least one gas distribution apparatus connectable to a process gas supply, the at least one gas distribution apparatus comprising at least one process gas flow aperture positioned so that a process gas supplied through the at least one gas distribution apparatus aperture flows circumferentially around an outer edge portion of the semiconductor wafer.

14. A process gas distribution device according to claim 13 wherein the at least one gas distribution apparatus is positionable in the reactor chamber to create flow from the gas distribution apparatus apertures which has a spray directional vector from more than 0° to less than 180° relative to a sidewall of the reactor chamber.

15. A process gas distribution device according to claim 14 wherein the spray directional vector is about 45°.

16. A process gas distribution device according to claim 13, wherein the at least one gas distribution apparatus is an injector.

17. A process gas distribution device according to claim 13 wherein the process gas comprises a fluorohydrocarbon gas.

18. A process gas distribution device according to claim 13 wherein the at least one gas distribution apparatus is positioned in the ceiling of the plasma reactor chamber.

19. A process gas distribution device according to claim 11 where in the injectors are mounted in a common gas feed chamber in the ceiling.

20. A method for treating a substrate in a gas plasma reactor comprising:
supplying a process gas to one or more gas distribution apparatus in the gas plasma reactor and providing a gas flow from each of the one or more gas distribution apparatus such that the combined gas flow from the one or more gas distribution apparatus is a circumferential gas flow along an outer edge portion of the substrate.

21. A method according to claim 20 further comprising converting the process gas in the gas plasma reactor into a plasma.

22. A method according to claim 20 further comprising creating a spray directional vector for the gas flow from each of the one or more gas distribution apparatus from greater than 0° to less than 180° relative to a sidewall of the reactor chamber, and away from the center of the wafer.

23. A method according to claim 22 wherein the spray directional vector is variable with the reactor chamber.

24. A method according to claim 22 wherein the spray directional vector is about 45°.

25. A method for creating a circumferential gas flow in a gas plasma reactor, comprising:
(a) creating at least a partial vacuum within an enclosed reactor chamber within the gas plasma reactor;
(b) injecting a process gas into the reactor chamber in a manner to create a substantially circumferential process gas flow around an outer edge portion of a substantially circular shaped semiconductor wafer substantially centrally positioned in said enclosed reactor chamber; and
(c) energizing the substantially circumferential process gas flow in the enclosed reactor chamber into a plasma state.
